(19) United States
(12) Patent Application Publication
(10) Pub. No.: US 2002/0167003 A1
(43) Pub. Date: Nov. 14, 2002

(54) Chemical and biological sensor using organic self-assembled transitors

(76) Inventors: Ian H. Campbell, Los Alamos, NM (US); Darryl L. Smith, Los Alamos, NM (US)

Correspondence Address: MADSON & METCALF, GATEWAY TOWER WEST, SUITE 900, 15 WEST SOUTH TEMPLE, SALT LAKE CITY, UT, 84101

(21) Appl. No.: 09/837,245

(22) Filed: Apr. 18, 2001

(51) Int. Cl. H01L 35/24; H01L 51/00

(52) U.S. Cl. 257/40

(57) ABSTRACT

An organic self-assembled transistor uses an organic self-assembled monolayer as the active semiconductor layer in which the conducting channel is formed. The monolayer is exposed to the atmosphere; thereby making the voltage characteristics of the transistor, such as mobility and density of charge carriers, very sensitive to vapor molecules. The chemical specificity and strength of interaction of the monolayer is tuned by varying the chemical end group of the organic molecules comprising the monolayer. Varying the chemical end groups allows fabrication of large transistor arrays easily tailored for sensor array or electronic nose applications. The monolayer is also compatible with known low-cost VLSI silicon fabrication processes.

### GOVERNMENT RIGHTS

This invention was made with Government support under Contract Number W-7405-ENG-36 awarded by the United States Department of Energy to the Regents of the University of California. The Government has certain rights in the invention.

### BACKGROUND OF THE INVENTION

1. Field of the Invention

The present invention relates generally to organic semiconductor transistors. More specifically, the present invention applies to organic self-assembled transistors for use with chemical and biological sensor applications.

2. Description of Related Art

Air quality has long been an important health concern. For example, miners used to bring a canary or other small sensor bird down into the mine to warn them if the air quality changed. If the air became dangerous the little sensor bird would stop chirping and in a worst-case die, thereby warning the miners to clear out of the area. Unfortunately, this type of “live” biological sensor exhibited many of the same problems that face modern biological and chemical sensors. Namely, it was very difficult to obtain immediate quantitative and qualitative information from the sensor. If the bird died, there was no way to determine exactly what type of vapor killed it (qualitative) or whether the death was a result of prolonged low-level exposure or of brief exposure to a saturated wave of poisonous gas (quantitative). Presently, modern resistor based sensors continue to have difficulty distinguishing related vapor molecules from each other, such as ethanol from methanol. In addition, residual amounts of vapor left on the sensor following exposure to ambient, reduce the sensor accuracy and require sensor recalibration. In addition, unless someone was assigned to watch the sensor bird, there was still a risk that the sensor bird would die without being noticed. Also, it was necessary for the person monitoring the sensor bird to be in the vicinity of the sensor to properly read it, exposing himself or herself to unnecessary risk. Most modem sensors, like the bird, require a large quantity or threshold of vapor be present before the sensor can give a warning response. With extremely toxic substances this warning may be too late to prevent dangerous exposure.

Many of these same biological sensor characteristics continue to plague modem chemical and biological sensors. For example, the detection accuracy of modem sensors deteriorates over time. This deterioration requires that the filters be replaced in order to maintain the accuracy of the sensor. This sensitivity deterioration also makes calibration a difficult process. The more comprehensive that the sensor is in detecting various analyte molecules, the more complex the calibration process for that sensor becomes. Also, each supplemental class of molecules detected by a sensor often requires additional electronics. As such the available comprehensive environmental sensors are often too large to be considered portable. Attempts to reduce sensor component size via inorganic and organic transistors have met with difficulty.

Specifically, electronic devices based on doped organic materials have not been developed as completely as doped inorganic semiconductors making response modeling of organic transistors unpredictable. Further, obtaining robust n-type and p-type doping of organic materials suitable for electronic device development has also proven difficult. Doped conducting materials, such as acid doped polymers, have electrical properties similar to low conductivity metals. Presently inorganic thin-film transistors employ undoped semiconductor layers and doped semiconductor contacts.

In contrast, conventional doped, inorganic transistors operate in either a charge accumulation or charge inversion mode, neither mode satisfying the previously mentioned sensor requirements. For example, a p-channel transistor in a charge inversion regime uses p-type semiconductor contacts and an n-type doped semiconductor layer in which the channel is formed. When sufficient gate bias is applied to the structure, an inversion layer is formed consisting of a thin p-type region in the n-type doped semiconductor adjacent to the gate insulator (the channel). The p-type doped semiconductor contacts make good electrical contact only to this inversion layer. In the “off” state, the leakage current is very low because the structure consists of a reverse biased diode in series with a forward biased diode. This high “off” state resistance is one advantage of doped inorganic transistors. Unfortunately, inorganic transistors are not as receptive to adsorption of vapor molecules and are thus less accurate.

Transistors operating in the accumulation regime utilize doped organic or semiconductor layers but, instead of forming an inversion layer, the channel is formed by biasing the gate to accumulate charge of the same type as the layer doping. For example, a p-type transistor has the gate biased so that additional holes accumulate adjacent to the gate insulator. Devices operating in the accumulation regime have large leakage currents and their total current is sensitive to the organic layer thickness. The poor leakage current and sensitivity to film thickness occur because the contacts are not rectifying, as they are in the inversion regime, so current can flow through the doped regions of the organic material independent of the gate bias. Therefore, it is not desirable to operate in an accumulation regime.

Additionally, the charge transport properties of organic materials, particularly at high carrier densities, are not very well understood. There are substantial discrepancies between a conventional inorganic FET model and organic device measurements. The most important properties to be included in an organic model are the charge density, the electric field dependence of the carrier mobility, and the contact interface electronic structure. These properties are important because the charge density and electric field in the organic material vary by many orders of magnitude. Including an accurate description of the mobility is important for calculating the charge density and potential profiles within the organic device. Modem organic models are analyzed using inorganic thin film transistor models, which use independent mobility, electric field, and charge density while ignoring the details of the interaction surrounding the contacts.

### SUMMARY OF THE INVENTION

The present invention provides an array of specialized sensor transistors easily tailored for sensor array or electronic nose applications. These qualities are primarily accomplished through an organic self-assembled monolayer exposed to the atmosphere. The monolayer is used in the sensor transistor as the active semiconductor layer in which the conducting channel is formed. Each transistor may be customized to detect molecules adsorbed on the organic self-assembled monolayer. The chemical specificity and strength of interaction of the monolayer may be selectively tuned by varying the chemical or sensing end group of the organic molecules comprising the monolayer. The adsorbed molecules are identified using the voltage characteristics, such as mobility and density of charge carriers, of the sensor transistors, which are very sensitive to vapor molecules. The sensor transistor can also be easily cleaned and recalibrated by heating the monolayer to repel the adsorbed molecules from the detection surface. The sensor transistor used in the present invention may be constructed using known low-cost Very Large Scale Integration (VLSI) silicon fabrication processes with the added step of micro-printing the sensitive organic self-assembled monolayer onto the sensor transistor after the high temperature processing.

The present invention has been developed in response to the current state of the art, and in particular, in response to these and other problems and needs that have not been fully or completely solved by currently available sensor or electronic nose applications. Thus, it is an overall object of the present invention to provide chemical and biological sensors via organic self-assembled transistors. This can be accomplished by operating the organic transistor with an organic self-assembled monolayer in a charge injection mode. An example of a sensor transistor using an organic self-assembled monolayer is shown in FIGS. 1-3. FIGS. 4 and 5 illustrate the responses of one embodiment of the present invention using fabricated organic transistors with a thin organic film, such as pentacene, as the active semiconductor layer.

Accordingly, one advantage the sensor transistor provides, while maintaining a desired diminutive overall size and cost, is an atomically sensitive surface that may be easily customized for various detection purposes. Other solutions, which may be available, compromise one of these elements.

Another advantage of the sensor transistor is that it may distinguish related vapor molecules from each other using transistor response, such as differential response.

Yet another aspect of the sensor transistor is the low threshold of vapor required before the sensor gives a warning response.

Another advantage of the sensor transistor is that the detection accuracy and calibration is easily maintained by periodic cleansing via relatively high current pulses that heat the organic layer and drive off adsorbed molecular species.

Additional objects and advantages of the invention will be set forth in the description which follows, and in part will be obvious from the description, or may be learned by the practice of the invention. The objects and advantages of the invention may be realized and obtained by means of the instruments and combinations particularly pointed out in the appended claims. These and other objects and features of the present invention will become more fully apparent from the following description and appended claims, or may be learned by the practice of the invention as set forth hereinafter.

### BRIEF DESCRIPTION OF THE DRAWINGS

In order that the manner in which the above recited and other advantages and objects of the invention are obtained, a more particular description of the invention briefly described above will be rendered by reference to specific embodiments thereof, which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 is a schematic illustration of an organic self-assembled transistor;

FIG. 2A is a schematic illustration of a molecule for self-assembly as illustrated in FIG. 1;

FIG. 2B is a molecular structure of one suitable chemical conjugated segment and suitable attaching end group;

FIG. 3 is a schematic illustration of a self-assembled monolayer channel in the ambient state for use with the present invention as illustrated in FIG. 1;

FIG. 4 is an exemplary graphical illustration of an organic transistor response;

FIG. 5 is an exemplary graphical illustration of the differential responses of an organic transistor upon exposure to different vapors relative to the organic transistor response illustrated in FIG. 4;

FIG. 6 is a block diagram of an exemplary sensor with an array of organic self-assembled transistors; and

FIG. 7 is a block diagram illustrating an exemplary sensor system that provides a suitable operating environment for one embodiment of the present invention.

### DETAILED DESCRIPTION OF THE PREFERRED EMBODIMENTS

FIG. 1 and the following discussion are intended to provide a brief, general description of a suitable operating environment in which the invention may be implemented. FIG. 1 is intended to be illustrative of potential systems that may utilize the present invention and is not to be construed as limiting. Those skilled in the art will appreciate that the invention may be practiced with many types of configurations, including organic transistors, self-assembled, and the like.

Reference is first made to FIG. 1, an organic transistor 100 or environment in which the present invention may be utilized or implemented. Organic transistors 100 are lateral devices consisting of a source electrode 104, drain electrode 106, a gate insulator 108, and a conducting gate contact 110. When a bias is applied between the gate 110 and source/drain electrodes 104 and 106, charges are injected into the organic film 102 from the source 104 and drain 106 contacts. With an additional bias applied between the source 104 and drain 106 contacts, a current flows laterally between these two contacts. The source to drain current is modulated by the gate voltage producing the transistor action.

Typically the organic transistors use undoped, insulating organic materials as the charge-transporting layers. The charge carriers in the devices are injected from the contacts. Because the organic material in which the channel is formed is undoped, all of the charge in the channel is injected from the contacts. At zero gate bias, the organic material contains no free charges except for a thin region (a few nanometers) near the contacts that contain charge thermally excited from the metals into the organic material. When a gate bias is applied to the structure, charges are injected into the organic material from both the source and drain contacts, forming a thin sheet of charge adjacent to the gate insulator (the channel). In the “on” state, the current flows through this thin sheet of charge. In the “off” state, the leakage current is low because of the high intrinsic resistivity of the undoped organic film. The substrate comprises a semiconductive material, such as silicon substrate 112.

The contacts are preferably Space Charge Limited (SCL) contacts, but those of skill in the art know that other contacts may also be used. SCL contacts provide the maximum current that the organic semiconductor material can support. These SCL contacts have a small energy barrier, less than about 0.3 eV, between the metal Fermi energy and the conduction or valence levels of the organic semiconductor. The small energy barrier allows SCL contacts to provide the maximum current. In contrast, non-SCL or Schottky contacts have a relatively large energy barrier, greater than about 0.4 eV, between the metal Fermi energy and the conduction or valence levels of the organic semiconductor. The large energy barrier blocks current flow from the metal to the semiconductor. Organic transistors that use non-SCL contacts thus require larger voltages and thus more power to achieve the same current and chemical sensitivity as transistors using SCL contacts.

The recent development of low operating voltage (about 5V) organic semiconductor transistors combined with progress in organic self-assembly techniques presents an opportunity to create a new class of organic self-assembled transistors (OSAT) 100 ideal for chemical and biological sensor applications. The OSAT 100 uses an organic self-assembled monolayer 102 as the active, semiconductor layer in which the conducting channel of the OSAT 100 is formed. The current is carried in this organic monolayer 102, about 3 nm thick, which is directly exposed to ambient. Since the current is carried in this surface monolayer 102, the current-voltage characteristics of the transistor are very sensitive to vapor molecules 114. The vapor molecules 114 change both the mobility and density of the charge carriers in the organic film 102. Each molecule produces distinct changes in the OSAT 100 response that can be used to identify the vapor molecule 114.

The OSAT 100 is fully compatible with silicon very large scale integration (VLSI) technology since the active organic monolayer 102 can be added after all of the high temperature silicon processing is completed. A schematic of an OSAT 100 fabricated on a silicon substrate 112 is shown in FIG. 1. In one embodiment of the invention, the semiconductor layer is the organic self-assembled monolayer 102, the source 104 and drain 106 contacts are metals, such as Al or Au, the gate insulator 108 is a high dielectric constant oxide, such as Ytrria Stabilized Zirconia (YSZ), and the gate contact 110 is n+silicon. The insulator 108 has a dielectric constant greater than about 4. The organic self-assembled monolayer 102 is deposited after the insulator 108 and contact layers 104 and 106 are fabricated so that the transistor can be made on a silicon VLSI substrate 112. The organic monolayer 102 can be extremely thin (<10 nm) because the charge in the organic layer forming the channel is electrostatically confined to the organic material only a few nm from the gate insulator 108. The transport properties of the thin organic layer are very sensitive to adsorbents on the surface of the monolayer 102. This sensitivity to adsorbents on the thin organic layer is the basis for the sensitivity of OSAT 100 based chemical and biological sensors.

The active layer of the OSAT 100 is a conjugated organic monolayer 102 that is directly exposed to the atmosphere to be probed. The self-assembly chemistry used to form the monolayer produces dense, defect free layers that are covalently bonded to the substrate and to each other. The monolayer is very stable physically and chemically. The length and surface density of the molecules in a typical conjugated organic monolayer 102 is about 3 nm long and covers about 10⁻¹⁴ cm². One embodiment of transistor structure with a monolayer area of 10⁻⁶ cm² (100 μm wide by 1 μm gate length) has a monolayer volume of 3×10⁻¹³ cm³ and contains 10⁸ organic molecules. Because the molecular layer is only a few nm thick, molecules adsorbed on its surface can have a strong effect on its properties. To detect small organic molecules, the transistor sensor could have a maximum response (assuming 1 molecule to be sensed on the surface of each molecule comprising the monolayer) with only 10⁸ adsorbed molecules or about 10⁻¹⁶ moles. It is possible to measure the transistor response well below the maximum surface coverage. This very small number of analyte molecules required for maximum response implies that the sensor can detect very low concentrations of volatile compounds and respond very quickly to moderate vapor concentrations.

Organic self-assembled transistors can be made by assembling the organic monolayer 102 on the gate insulator 108 of transistor structures produced on silicon VLSI substrates 112. The VLSI substrate 112 would contain the gate insulator 108, gate 110, source contact 104, and drain contact 106 of the OSAT in addition to conventional silicon circuitry for readout and processing. An appealing method to deposit a wide range of organic monolayers 102 is to use micro-contact printing (MCP), a low cost fabrication process. In MCP, an elastomeric stamp is used to transfer the monolayer 102 to the substrate 112 and insulator 108 by physical contact. The stamp is shaped so that when it is pressed against the insulator 108 or substrate 112, the monolayer molecules 200 are transferred from the stamp to the substrate 112 in the desired pattern. This technique has been demonstrated to have submicron spatial resolution. The quality of the self-assembled monolayers 102 formed using this procedure is as good or better than layers formed using solution methods.

To produce a large array of sensors with different monolayers, the substrate would be printed multiple times using stamps with different patterns inked with different molecules for each distinct monolayer. Another feature of using robust silicon structures is that the silicon circuitry and substrate can be reused. To reuse the structures only the organic monolayers need to be removed, in fact only a portion of the monolayer need be replaced for recalibration to occur. Complete removal could be accomplished using a short plasma etch with oxygen or hydrogen if the silicon circuitry is properly encapsulated. A new monolayer could then be applied to the substrate to form a new OSAT.

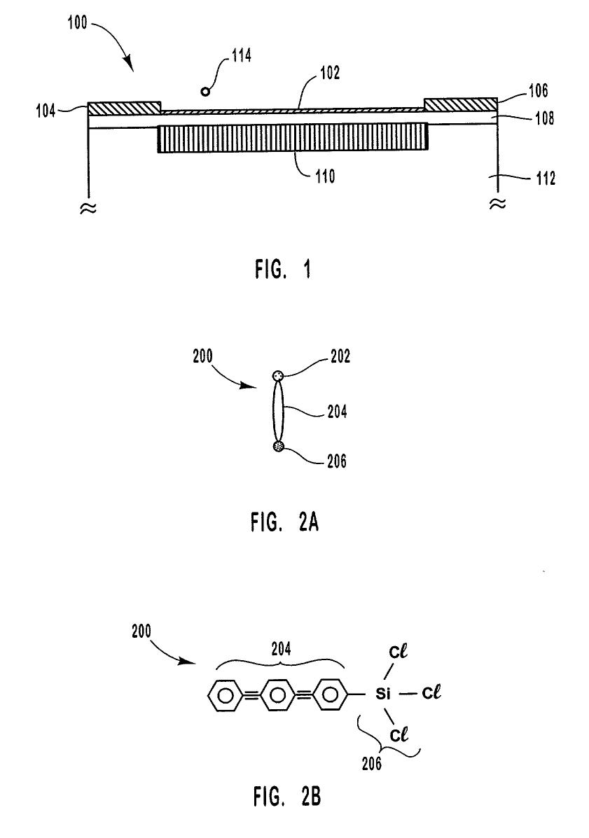

FIG. 2A is a schematic view of the molecules used to form the organic self-assembly monolayer shown in FIG. 1. The self-assembly molecule 200 consists of a conjugated segment 204 with two end groups, a sensing end group 202, and an attaching end group 206.

The organic molecules used to form the self-assembled monolayer 102 consist of a conjugated segment 204 that carries the transistor current terminated by two functional end groups. One attaching end group 206 is used to covalently attach the molecule to the gate insulator 108 (and to neighboring molecules in the self-assembled monolayer) and the other sensing end group 202 defines the chemistry of the surface used to sense vapor molecules. As illustrated in FIG. 2B, one can use the same attaching end group 206 to attach to the insulator 108 and the same conjugated molecule 204 to carry the current varying only the terminal sensing end group 202 that determines the sensor interaction. It is therefore possible to produce an array of transistor sensors with very similar initial I-V characteristics (same current carrying molecule) but that interact very differently with the atmosphere due to variations in the sensing end group 202.

This property makes it convenient to make large arrays by combining multiple sensor elements. Each sensor element uses identical electronics for common sensor functions, such as the readout components, but allow for an almost unlimited range of detection responses on the sensor transistors via variations to the sensing end group 202. Exemplary sensing end groups 202 include halides, nitrites, ketones, amines, amides and the like. Halides are useful for detecting alcohols, amides, and acids. While sensing end groups 202 that use nitrile help detect NOₓ, amino acids, and proteins. Ketone may be used as a sensing group for detecting esters. The amines and amides are useful in detecting halides and bases.

Exemplary conjugated segments 204 include Phenyl-acetylene and Phenylene-vinylene. FIG. 2B illustrates the molecular structure of a conjugated segment 204 using Phenyl-acetylene. Phenyl-acetylene segments 204 exhibit several useful properties, for example they are very rigid and form high areal density monolayer films. The rigidity and high packing density allow charges to move efficiently through conjugated segments 204 comprising Phenyl-acetylene. An alternative embodiment uses phenylene-vinylene conjugated segments 204, which are useful for sensing small molecules, such as methane, silane, methanol, and the like.

FIG. 2B further illustrates the molecular structure of a trichlorosilyl group used as an attaching end group 206. The trichlorosilyl group is one preferred family of attaching end groups 206, because they produce the strongest and most durable organic semiconductor layer. These trichlorosilyl based attaching end groups 206 form strong covalent bonds to the oxide surface and to each other. Other exemplary attaching end groups 206 include amine and carboxylic acid groups. These groups form relatively weak ionic bonds to the oxide surface, which may be suitable for disposable or field produced/repairable sensors.

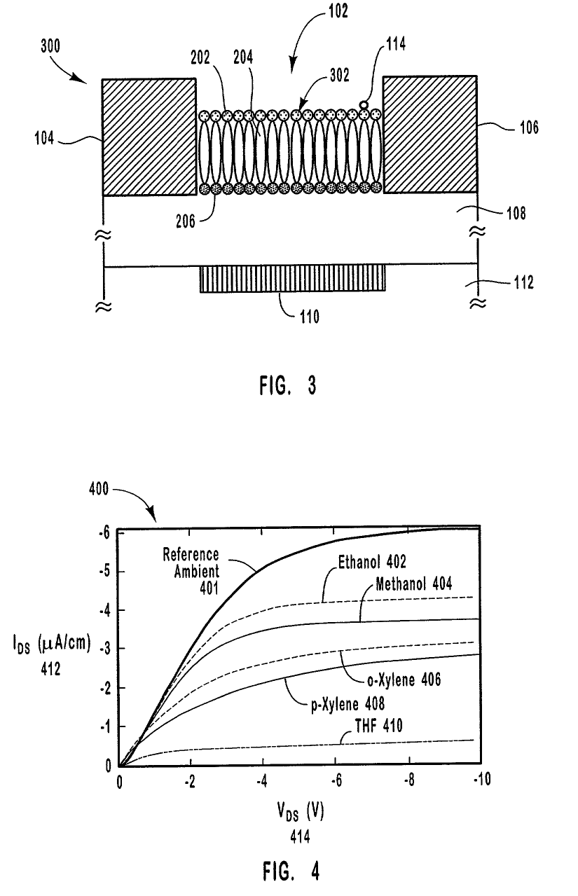

FIG. 3 illustrates the ambient state of a self-assembled monolayer channel for use with the present invention as illustrated in FIG. 1. Specifically, the sensing end group surface 302 is in contact with ambient conditions. A close up schematic of the OSAT 300 is also shown in FIG. 3. The use of self-assembly techniques allows the fabrication of a dense, highly ordered organic monolayer 102 with an atomically sharp interface in the sensing end group surface 302. Changing the sensing end group 202 of the molecule can control the chemical properties of the sensing surface 302. The conjugated segment 204 and attaching end group 206 can be kept constant. It is therefore possible to produce an array of transistor sensors with very similar initial I-V characteristics (same current carrying molecules) but that interact very differently with the atmosphere due to variations in the sensing end group 202. This property makes it convenient to make large arrays using identical electronic readout components and still allow a wide range of responses. The ability to combine a very large number of sensor interactions on a convenient silicon VLSI template allows production of chemical and biological sensors that can detect and distinguish a large number of volatile compounds.

Analogous to inorganic transistors, organic self-assembled transistors can be n-channel or p-channel devices. For OSAT sensor applications, this can be significant since the positive or negatively charged channel is only a few angstroms from the molecule to be detected. The proximity of the charged channel and the vapor molecule means that electrostatic interactions could be used to distinguish molecules. For example, a molecule with a permanent dipole moment would orient itself differently on the surface of opposite polarity devices. The change in orientation would produce a different effect on the transistor characteristics. Unlike conventional inorganic transistors, the polarity of the organic transistor is largely determined by the type of metal used for the drain and source contacts. The organic material is undoped and the charge is injected into the molecule directly from the contacts. One embodiment of n-channel devices uses low work function metals (e.g. Al). While another embodiment of p-channel devices uses high work function metals (e.g. Au). Thus, it is possible to produce arrays of n- and p-channel devices using the same organic molecules within a sensor device simply by using different metal contacts on the silicon substrate.

Restoring the transistor 300 following a detection cycle requires removal of adsorbed molecules from the sensing end group surface 302 so that the transistor 300 can respond to its ambient with a clean surface. Because the drain-source resistance can be varied over many orders of magnitude, it is possible, using conventional circuitry, to use relatively high current pulses to heat the organic layer and drive off adsorbed molecular species. Very little energy is required to heat the thin organic film. Assuming an organic monolayer volume of 3×10⁻¹³ cm³ (see above) the energy required to heat the layer 50° C. is only 15 pJ. For example, the low current transistor response can be measured frequently and when a significant response is detected the surface could be thermally cleaned to refresh or reset the transistor sensor. This enables increased sensitivity and more rapid response times by cleaning the interacting surface of adsorbed molecules.

As previously described, organic self-assembled transistors used for chemical and biological sensor applications provide several advantages over the existing art, such as: 1) monolayer sensitivity, 2) chemically tailored surface, 3) spectroscopic readout, 4) silicon VLSI compatibility, 5) complementary polarity devices, and 6) thermal surface cleaning.

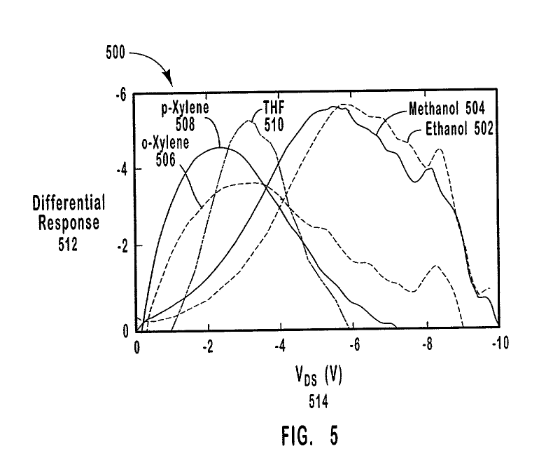

To illustrate the advantages of spectroscopic readout of organic self-assembled transistors for chemical and biological sensor applications, FIGS. 4 and 5 show responses of fabricated organic transistors using thin organic films as the active semiconductor layer. The transistors were fabricated on silicon substrates using Pt source and drain contacts and YSZ as the gate insulator. Pentacene films about 10 nm thick were used in place of the organic self-assembled monolayer. The transistor current-voltage characteristics at fixed gate voltage are shown in FIG. 4. A transistor is a three terminal device and thus its current-voltage (I-V) characteristics contain more information than those of two terminal devices such as resistors. The I-V characteristics are often presented as shown in FIG. 4 where the drain-source current is shown as a function of drain-source voltage at a fixed gate bias.

The transistor characteristics are usually described by its gate threshold voltage and charge carrier mobility. The transistor response to a molecule 114 on its surface 302 will affect both of these parameters. The control of sensing end group surface properties 302 based on varying the end groups of organic self-assembled monolayers is well known to one of skill in the art. For example, the transistor responses from a variety of surfaces 302 with different adsorption isotherms, electron withdrawing, or electron donating groups can be used to identify vapor species. Therefore, it is possible to distinguish vapor molecules absorbed on the surface 302 based on the transistor response as a function of drain-source and/or gate-source voltage. Measuring this rich set of data from transistor sensors will facilitate discriminating and identifying target compounds.

The I-V characteristics shown in FIG. 4 are for the following exposure conditions: ambient 401, and 1 part-per-thousand each of ethanol 402, methanol 404, o-xylene 406, p-xylene 408, and tetrahydrofuran (THF) 410. In all cases, exposure to the vapor decreases the drain-source current 412. The changes in the drain-source current 412 are functions of the drain-source voltage 414, that is, the shape of the I-V curves are different for each molecule. The change in shape of the I-V characteristic shows that it is possible to distinguish molecules from their distinct responses as a function of voltage.

To illustrate this, consider the differential response 512, R, of the transistor as illustrated in FIG. 5. The differential response 512 is the derivative of the drain-source current with respect to the drain-source voltage of the reference ambient response divided by the derivative of the drain-source current with respect to the drain-source voltage of the sensor gas response at constant gate voltage, as illustrated by equation 1:

$$R = \frac{( \frac{\partial {I}_{R}}{\partial {V}_{R}} )}{{( \frac{\partial {I}_{S}}{\partial {V}_{S}} )}_{{V}_{G}}} \qquad Equation 1$$

Where I_{R} is the drain-source current and V_{R} is the drain-source voltage of the reference ambient response. While I_{S} is the drain-source current and V_{S} is the drain-source voltage of the sensor gas response.

FIG. 5 illustrates the differential response 512 of the transistor upon exposure to different vapors. The alcohol 502 and 504, xylene 506 and 508, and THF 510 molecules have substantially different differential responses as a function of voltage. The two alcohol molecules 502 and 504 have peaks about 5-6V and the two xylene molecules 506 and 508 have peaks about 2-3V. The THF molecule 510 has a sharper peak about 3V. Furthermore, ethanol 502 can be distinguished from methanol 504 and o-xylene 506 distinguished from p-xylene 508 using this analysis. The large amount of information available from a single organic transistor in a chemical/biological sensor array adds significantly to its ability to discriminate and identify molecules. The response time of these organic thin-film transistors is a few seconds at concentrations of about one part per thousand. The response time of organic self-assembled transistors is even faster. The response time of the organic thin-film transistors is limited by the time required for the gas molecules to diffuse through part of the thin organic film to reach the conducting channel. The OSATs do not have this delay.

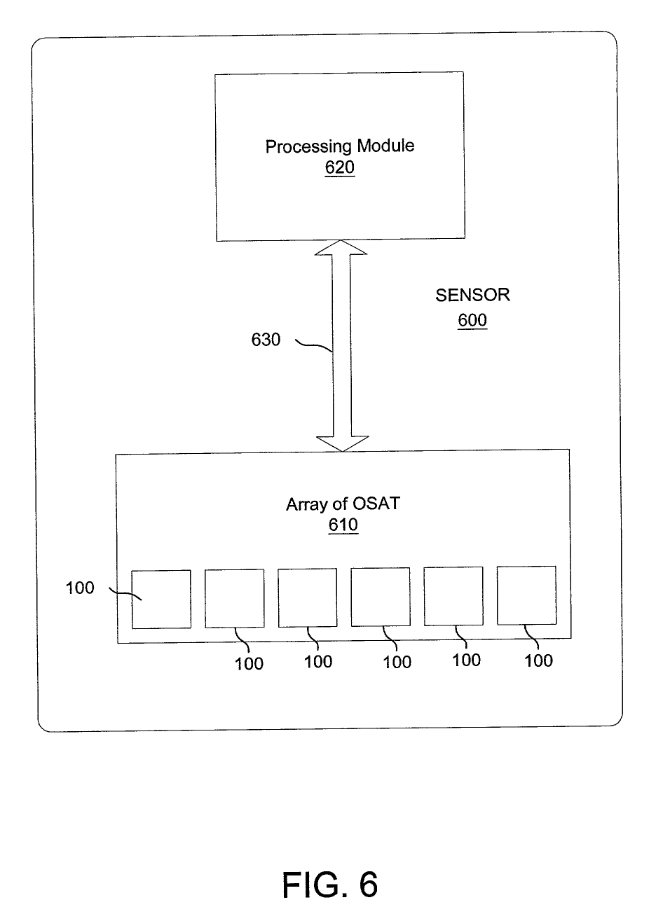

FIG. 6 illustrates an exemplary sensor 600 in accordance with one embodiment of the present invention. The organic monolayer fabrication capabilities previously discussed, such as MCP, help produce a novel class of extremely versatile and sensitive chemical and biological sensors 600. Specifically, the exemplary sensor 600 includes an array 610 of organic self-assembled transistors 100 that may be individually monitored by a processing module 620 using conventional circuitry 630, such as a data bus.

The array 610 may be constructed using known low-cost VLSI silicon fabrication processes with the added step of micro-printing a customized sensitive organic self-assembled monolayer onto each sensor transistor 100. Using an organic self-assembled monolayer as the active semiconductor layer in which the conducting channel is formed in transistors 100, the present invention is able to provide an array 610 of specialized transistors 100 easily tailored for sensor array or electronic nose applications. Each transistor 100 is customized to detect molecules adsorbed on the organic self-assembled monolayer exposed to the atmosphere. The adsorbed molecules are identified using the voltage characteristics, such as mobility and density of charge carriers, of the sensor transistors 100, which are very sensitive to vapor molecules. The chemical specificity and strength of interaction of the monolayer may be selectively tuned by varying the chemical or sensing end group of the organic molecules comprising the monolayer. The array 610 can also be easily cleaned and recalibrated by heating the monolayer of each transistor 100 to repel the adsorbed molecules from the detection surfaces.

In various embodiments, the processing module 620 controls the operation of the array 610, including the other components thereof that are also connected to the processing module 620. In addition to control functions, the processing module 620 also receives and correlates detection data from the array 610 via conventional circuitry 630. The detection data sent to the processing module 620 may include differential response and voltage characteristics of the sensor transistors 100, such as the mobility and density of charge carriers. In one embodiment, the processing module 620 compares the detection data against expected characteristic transistor responses and indicates when they do not match. The processing module may be embodied as a central processing unit (CPU), a microcontroller, a microprocessor, a digital signal processor (DSP), a state machine, a programmable logic device, an application specific integrated circuit (ASIC), a general-purpose computing device, or other device known in the art.

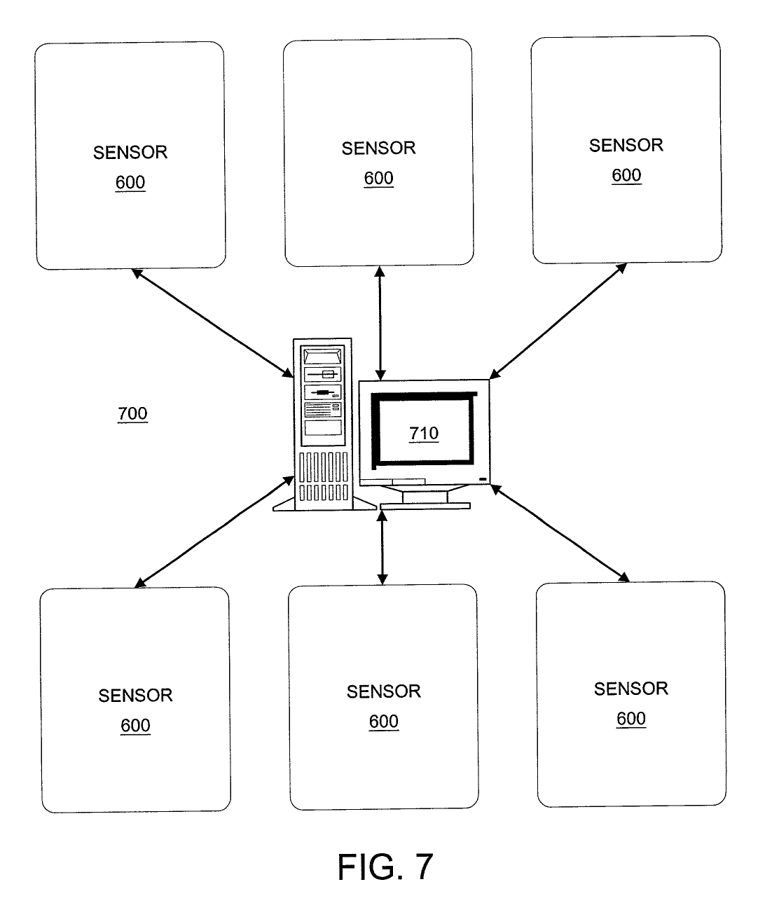

FIG. 7 and the following discussion are intended to provide a brief, general description of a suitable environment in which the invention may be implemented. Reference is first made to FIG. 7 illustrating an exemplary sensor system 700 or environment in which the present invention may be utilized or implemented. FIG. 7 is intended to be illustrative of potential systems that may utilize the present invention and is not to be construed as limiting. Sensor system 700 uses a centrally located computer 710 in communication with various chemical and biological sensors 600 to monitor sensor responses. This sensor configuration allows a detection perimeter to be monitored from a central location. Another advantage of this remote sensor configuration is that critical locations may be continual monitored without requiring the individual monitoring the sensor to be in the proximity of the location.

Those skilled in the art will appreciate that the invention may be practiced with many types of computer system configurations 710, including processing modules as previously described, personal computers, hand-held devices, multi-processor systems, microprocessor-based or programmable consumer electronics, network PCs, minicomputers, mainframe computers, Personal Digital Assistants, and the like.

In one embodiment, the sensor 600 includes a plurality of organic self-assembled transistors, in which each transistor is selectively tuned via sensing end groups to detect different vapor molecules. In this manner the array of specialized transistors allow each sensor 600 to remotely monitor multiple atmospheric conditions. One additional sensor configuration analyzes transistor responses against expected threshold values prior to transmitting detection data to the centrally located processing module 710. These sensors 600 partially incorporate the processing module locally, thereby reducing unnecessary communication with a centralized sensor server.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed and desired to be secured by United States Letters Patent is:

1. An apparatus for providing chemical and biological detection of molecules adsorbed on an organic self-assembled surface, comprising:
a gate contact;
a gate insulator attached to the gate contact;
a source contact attached to the gate insulator;
a drain contact attached to the gate insulator; and;
a semiconductor layer extending between the source and drain comprising an organic monolayer of molecules, each molecule comprising a sensing end group, a conjugated segment covalently bonded to the sensing end group, and an attaching end group covalently bonded to the conjugated segment and attached to the gate insulator.

2. The apparatus as recited in claim 1, wherein the sensing end group is selected from the group consisting of halides, nitrites, amines, amides, and ketones.

3. The apparatus as recited in claim 1, wherein the attaching end group is selected from the group consisting of trichlorosilyl groups, amines, and carboxylic acid groups.

4. The apparatus as recited in claim 1, wherein the conjugated segment is selected from the group consisting of phenyl-acetylene and phenylene-vinylene.

5. The apparatus as recited in claim 1, configured such that adsorbed molecules can be selectively removed from the sensing end group by heating the organic self-assembled monolayer and driving off adsorbed species of vapor molecules.

6. The apparatus as recited in claim 1, wherein the sensing end group generates an atomically sharp interface for differentiating between vapor molecules.

7. The apparatus as recited in claim 1, wherein a substance is detected when the sensing end group adsorbs a threshold amount of a desired vapor molecule.

8. An organic self-assembled transistor fabricated on a silicon substrate, the transistor comprising:
a gate contact;
a gate insulator attached to the gate contact;
a source contact attached to the gate insulator;
a drain contact attached to the gate insulator; and
a semiconductor layer between the source and drain, the layer comprising an organic self-assembled monolayer of molecules.

9. The transistor as recited in claim 8, wherein the organic self-assembled monolayer comprises a pentacene film.

10. The transistor as recited in claim 9, wherein the pentacene film is about 10 nm thick.

11. The transistor as recited in claim 8, wherein each molecule of the organic self-assembled monolayer comprises:
a sensing end group;
a conjugated segment covalently bonded to the sensing end group; and
an attaching end group covalently bonded to the conjugated segment and attached to the gate insulator.

12. The transistor as recited in claim 11, wherein the sensing end group can be changed to control the chemical properties of the sensing surface.

13. The transistor as recited in claim 11, wherein the organic self-assembled monolayer generates an atomically sharp interface for differentiating between vapor molecules via the sensing end group.

14. The transistor as recited in claim 11, wherein the sensing end group is selected from the group consisting of halides, nitrites, amines, amides, and ketones.

15. The transistor as recited in claim 11, wherein the conjugated segment is selected from the group consisting of phenyl-acetylene and phenylene-vinylene.

16. The transistor as recited in claim 11, wherein the attaching end group is selected from the group consisting of trichlorosilyl, amines, and carboxylic acid groups.

17. The transistor as recited in claim 11, wherein charge carrier density of the sensing end group changes according to the adsorption of vapor molecules.

18. The transistor as recited in claim 11, wherein charge mobility of the sensing end group changes according to the adsorption of vapor molecules.

19. The transistor as recited in claim 11, wherein current pulses heat the organic self-assembled monolayer so that adsorbed species of vapor molecules are removed from the sensing end group.

20. The transistor as recited in claim 19, wherein the energy required to heat 3×10⁻¹³ cm³ of the organic self-assembled monolayer is about 15 pJ.

21. The transistor as recited in claim 11, wherein the sensing end group may be removed and replaced without removing the conjugated segment or the attaching end group.

22. A process of making an organic self-assembled transistor on a silicon substrate, the process comprising the steps of:
high-temperature processing of the silicon to generate a substrate, a gate, a gate insulator, a source and a drain for the transistor; and
depositing an active organic monolayer between the source and drain, the active monolayer attaching to the gate insulator via an attaching end group.

23. The process as recited in claim 22, wherein the active organic monolayer is deposited using micro-contact printing.

24. The process as recited in claim 23, wherein the depth of the active organic monolayer is between about 3 nm and about 10 nm.

25. The process as recited in claim 22, wherein the depth of the active organic monolayer is less than about 10 nm.

26. The process as recited in claim 22, wherein differential response characteristics of the active organic monolayer vary according to concentration levels of adsorbents on the surface of the monolayer.

27. The process as recited in claim 22, wherein the active organic monolayer comprises a conjugated segment covalently bonded to said attaching end group and a sensing end group covalently bonded to said conjugated segment.

28. The process as recited in claim 27, wherein the sensing end group can be changed to control the chemical properties of the sensing surface.

29. The process as recited in claim 27, wherein said attaching end group is chemically bonded to the gate insulator.

30. The process as recited in claim 22, wherein the substrate is a silicon substrate and wherein the contacts are metals.

31. The process as recited in claim 30, wherein the contacts are selected from the group consisting of gold, aluminum, silver, platinum, copper, lithium, calcium, and combinations thereof.

32. The process as recited in claim 22, wherein the gate insulator is a high dielectric constant oxide.

33. The process as recited in claim 32, wherein the gate insulator is ytrria stabilized zirconia.

34. The process as recited in claim 32, wherein a dielectric constant of the gate insulator is greater than about 4.

35. A chemical and biological sensor array system, the system comprising:
an array of organic self-assembled single transistor sensors;
a processing module; and
silicon circuitry connecting the array to the processing module.

36. The system as recited in claim 35, the array of organic self-assembled transistors further comprising at least two organic self-assembled transistor sensors calibrated to detect different vapor molecules.

37. The system as recited in claim 36, wherein the processing module monitors differential responses from organic self-assembled transistors in the array, the processing module detecting changes in the differential responses associated with the adsorption of vapor molecule species.

38. The system as recited in claim 35, wherein the silicon circuitry configured such that the transistor sensors can be packaged as an integrated circuit where the organic self-assembled transistor sensors are exposed to the testing atmosphere.

39. The system as recited in claim 35, wherein the organic self-assembled single transistor sensor comprises:
a transistor including a source, a drain, a gate, and a gate insulator; and
a semiconductor self-assembled monolayer channel bonded to the gate insulator between the source and drain of the transistor, the monolayer changing charge mobility and charge density upon adsorption of vapor molecules.

40. The system as recited in claim 39, wherein the monolayer comprises individual organic monolayer molecules for self-assembly covalently bonded to other surrounding organic monolayer molecules.

41. The system as recited in claim 40, wherein the monolayer provides maximum response when each of the molecules adsorbs a desired vapor molecule.

42. The system as recited in claim 39, wherein the monolayer provides measurable transistor response changes to low concentrations of less than 10⁻¹⁶ moles of analyte molecules.

43. The system as recited in claim 39, wherein the monolayer provides maximum response in the presence of analyte molecules even at low concentrations of about 10⁻¹⁶ moles.
